(19) United States
(12) Patent Application Publication
(10) Pub. No.: US 2005/0236644 A1
(43) Pub. Date: Oct. 27, 2005

(54) Sensor packages and methods of making the same

(76) Inventors: Greg Getten, Pulau Pinang (MY); Masli Bin Yahaya, Kedah (MY)

Correspondence Address: LAWRENCE Y.D. HO & ASSOCIATES PTE LTD, 30 BIDEFORD ROAD, #07-01, THONGSIA BUILDING, SINGAPORE, 229922, SG

(21) Appl. No.: 10/832,362

(22) Filed: Apr. 27, 2004

(51) Int. Cl. H01L 21/44

(52) U.S. Cl. 257/106

(57) ABSTRACT

The present invention provides a sensor package, wherein the sensor package comprises a leadless frame having a plurality of inner leads and a plurality of external leads, a molded structure forming an open cavity, wherein the leadless frame forms the bottom of the open cavity, and wherein the plurality of external leads expose to the outside of the open cavity and the plurality of inner leads expose to the inside of the open cavity, a sensor die attached to the bottom of the open cavity, a plurality of bond wires electrically connecting the sensor die with the plurality of inner leads, and a filler gel filling the open cavity to encapsulate the sensor die and bond wires.

### FIELD OF THE INVENTION

The present invention generally relates to semiconductor packages, and more particularly to sensor chip packages and methods for manufacturing of sensor chip packages.

### BACKGROUND OF THE INVENTION

Sensor chips are usually packaged one way or the other so that the sensor chips are shielded from the ambient environment for better performance. In addition, the package materials provide the sensor chips with physical strength so that the sensor chips could be used in different conditions. There are available of many kinds of sensor chips including pressure sensor chips.

A conventional pressure sensor chip has a relatively thick base and thin diaphragm. Strain gauges are formed on the surface of the diaphragm by thin-film forming technology. Thus, the pressure sensor chip is susceptible to mechanical damage during handling and packaging. For this reason, these sensor chips previously have been mounted in premolded packages and then sealed in the package using a separate cover. Otherwise, if such a sensor chip were subjected to conventional packaging process such as, for example, injection molding, the sensitive membrane of the chip would be destroyed by the high pressures exerted on the membrane by the injected molding compound.

The current sensor package methods have many shortcomings. For example, pre-molded packages for mounting a sensing chip typically have a plurality of leads protruding therefrom, so that they are bulky and difficult to handle in an automatic assembly line.

Therefore, there is an imperative need to have a sensor package having small dimensions and leadless contact pads. This invention satisfies this need by disclosing methods of making small size sensor chip packages. Other advantages of this invention will be apparent with reference to the detailed description.

### SUMMARY OF THE INVENTION

The present invention provides a sensor package, wherein the sensor package comprises a leadless frame having a plurality of inner leads and a plurality of external leads, a molded structure forming an open cavity, wherein the leadless frame forms the bottom of the open cavity, and wherein the plurality of external leads expose to the outside of the open cavity and the plurality of inner leads expose to the inside of the open cavity, a sensor die attached to the bottom of the open cavity, a plurality of bond wires electrically connecting the sensor die with the plurality of inner leads, and a filler gel filling the open cavity to encapsulate the sensor die and bond wires.

The present invention also provides a method of manufacturing a sensor package, wherein the method comprises steps of providing a leadless leadframe with a plurality of inner leads and a plurality of external leads, molding the leadless leadframe to form a molded structure with an open cavity, wherein the leadless leadframe forms the bottom of the open cavity, attaching a sensor die onto the bottom of the open cavity, electrically connecting the sensor die and the plurality of inner leads by wire bonding, and filling the open cavity with a filler gel, thereby the sensor die and bond wires are encapsulated by the filler gel.

The objectives and advantages of the invention will become apparent from the following detailed description of preferred embodiments thereof in connection with the accompanying drawings.

### BRIEF DESCRIPTION OF THE DRAWINGS

Preferred embodiments according to the present invention will now be described with reference to the Figures, in which like reference numerals denote like elements.

FIG. 1 shows a portion of a panel of leadframes which can be formed in any section of a leadframe strip.

FIG. 2 shows one unit of the leadframes as shown in FIG. 1 in accordance with one embodiment of the present invention.

FIG. 3 is a perspective view of a final sensor package in accordance with one embodiment of the present invention.

FIG. 4 is a perspective view of a molded leadframe with an open cavity.

FIG. 5 is a cross-section view of a finished sensor chip package with a flat leadframe.

FIG. 6 is a cross-section view of a finished sensor chip package with a “stamped” or “bent” leadframe.

### DETAILED DESCRIPTION OF THE INVENTION

The present invention may be understood more readily by reference to the following detailed description of certain embodiments of the invention.

Throughout this application, where publications are referenced, the disclosures of these publications are hereby incorporated by reference, in their entireties, into this application in order to more fully describe the state of art to which this invention pertains.

The present invention provides sensor chip packages for diversified applications. While the detailed description is focused on the pressure sensor chip packaging, it is to be appreciated that the methods disclosed herein are applicable to other sensor chips including accelerometer sensor, camera-image sensor, and IR/UV sensor.

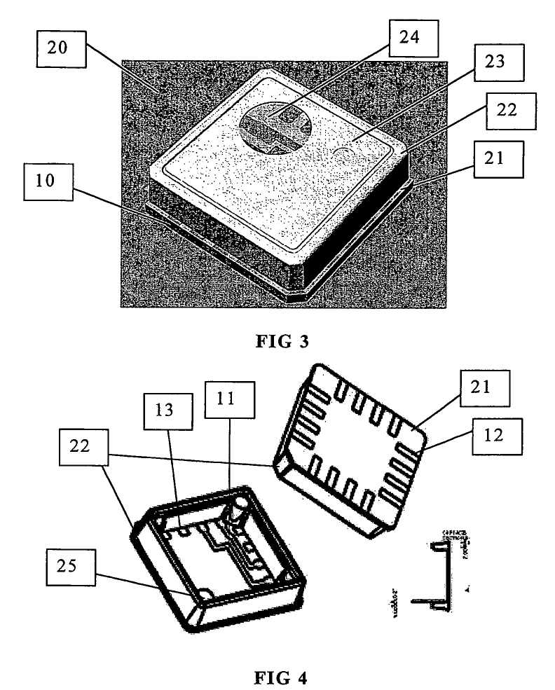

In one embodiment, the present invention provides a pressure sensor package as shown in FIG. 3. The pressure sensor package 20 comprises a bottom 21, a side wall 22, and a lid 23 with a window 24. The bottom 21 is formed by molding over a leadframe to be discussed in detail hereinafter. The side wall 22 is molded together with the bottom 21 to form an open cavity in which a sensor chip is disposed. The open cavity can be optionally filled with a suitable filling gel after the sensor chip is disposed within and bonded to inner contact pads by conductive wires. After the gel filling, the open cavity is capped by the lid 23. The window 24 allows the sensor chip to function properly.

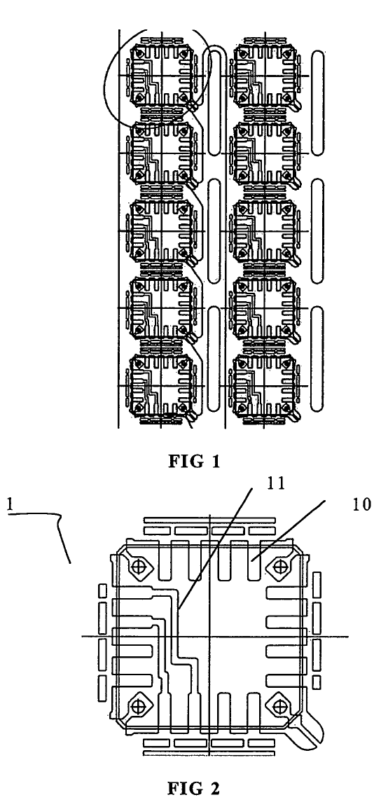

Now referring to FIG. 1, there is shown a portion of a leadframe strip. The leadframe strip is divided into a plurality of sections, each of which incorporates a plurality of leadframe units. FIG. 2 shows one unit of the leadframes as shown in FIG. 1. The unit of leadframe shown in FIG. 2 as one embodiment of the present invention has a plurality of contact leads 10 disposed at the periphery of the unit. In this specific embodiment, a plurality of inner connectors 11 connecting two non-adjoining contact leads. The inner connectors 11 may be half-etched from the bottom surface so that they are not exposed to the outer surface after the leadframe strip is molded. In addition, the lower surface of each lead is preferably smaller than the upper surface thereof such that each lead has a tapered profile.

In certain embodiments, each unit of the leadframe may comprise one or more die attach pads and a plurality of leads arranged about the periphery of the die attach pads. The die attach pads are connected to the leadframe by supporting bars. Preferably, the lower surface of the die pad is smaller than the upper surface thereof such that the die pad has a tapered profile, and the lower surface of each lead is smaller than the upper surface thereof such that each lead has a tapered profile. The tapered profile is supposed to avoid the delamination problem of the sensor packages.

The leadframe in accordance with the present invention is formed from a thin metal strip which has been etched or stamped to form a pattern similar to that shown in FIG. 1. Preferably, the leadframe is made of copper or alloys containing copper. Alternatively, the leadframe is made of iron, nickel or alloys thereof, and then plated with copper.

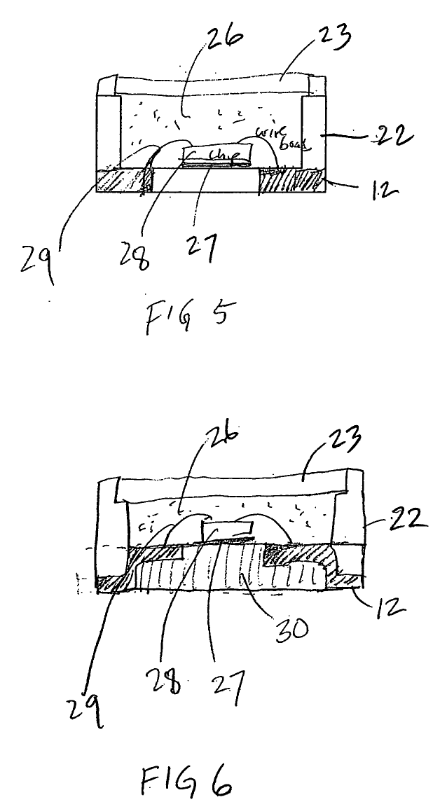

In some circumstances, the bottom of a sensor package may need to be thickened for higher physical strength. This is especially true when there is no die attach pad provided. Therefore, there is provided a unique “stamped” and “bent” leadframe formed by “stamping” and “bending” a conductive material such as copper, with an effective leads and effective a bend, the unique stamped and bent leadframe being uniquely compressively retained by a mold (not shown), in accordance with the present invention. This will be seen in FIG. 6.

Furthermore, the leadless leadframe may be fabricated by Ag plating or doping.

After forming the leadframe strip, the strip is conventionally molded using a mold in which the bottom plate is a flat plate, so that the molding compound exposes the bottom surfaces of the leads. The molding technology is well known to one skilled in the art so that there is no detailed discussion about the molding technology in order not to obscure the present invention. Preferably, liquid silicone rubber adhesive is applied to the back surface of the leadframe strip by a conventional method. The thickness of the adhesive is set to some tens of micrometers. In some embodiments, nonsilicone type may be used as the adhesive.

In certain embodiments, an organic film (e.g., high temperature polyimide or other high temperature stable organic compound) is applied to the back surface of the leadframe strip. The organic film is precoated with at tacky adhesive, resulting in an organic film tape, which holds the leadframe strip in place during processing and also stops mold flash from accumulating on the leads. When the film is fed to cover the surface of the lower part of the molding die, air is sucked through a plurality of through-holes by an air suction mechanism (not shown) such that the film is fixed on the lower part of the molding die. The upper part of the molding die has a cavity shaped generally to conform to the to-be-molded shape of the leadless semiconductor chip package. Preferably, the film is made of heat-resistant and elastic materials such as Teflon (polytetrafluoroethylene, PTFE) or ETFE (ethylene tetrafluoroethylene). The mold member includes polybutylene terephthalate (PBT), polyphenylene sulfide (PPS), epoxy, and silicone rubber.

The molding die is closed and clamped together in a manner that the semiconductor die is positioned in the cavity and the leadframe is disposed against the film. After that, a hardenable molding compound is transferred into the cavity. When the molding compound hardens, the molding die is unclampled and opened to take out the molded product. The film provides better sealing effect to prevent flash from forming on the lower surface of the molded structure.

The molded structure with an open cavity in accordance with one embodiment of the present invention is shown in FIG. 4. After molding, the external leads 12 are exposed to the outside environment to allow the external leads to interact with other electrical components. The inner leads 13 are exposed to the open cavity to all the inner lead to be bonded with sensor die and/or IC chips to be disposed within the open cavity. As discussed above, the inner connectors 11 may be preferably half-etched before molding. Thus, the inner connectors 11 can only be seen in the open cavity, but not in the outer surface. Finally, a cylindrical pole 25 may be optionally disposed at each corner of the sensor package to provide physical strength.

After the open cavity is formed, at least one sensor chip is disposed within it. The number and type of chips to be disposed within the open cavity are easily determined by specific applications. In certain embodiments, other IC chips may also disposed within the open cavity conforming to certain applications. The sensor chip and the IC chip are previously formed. In one embodiment, a silicon chip having a thickness of 0.5 mm to 0.6 mm is used as the sensor chip.

The sensor chips and/or the IC chips are bonded on the bottom of the open cavity with adhesive. When the die attach pad is provided within the open cavity, the sensor chip and/or IC chip are preferably disposed onto the die attach pad. Thereafter, the adhesive is heated to a predetermined temperature, which hardens the adhesive. The adhesive is preferably a silicone type, which enables a flexible adhesion. In one embodiment, the adhesive is a silicone rubber type thermosetting one-component adhesive. As long as a sensor chip is flexibly secured, the adhesive may be a fluorine type, soft epoxy, or urethane type. Chips can also be attached with a standard epoxy.

After die bonding, the lead frames are set on a wire bonder, and wire bonding is performed using known wire bonding techniques. That is, the sensor chip and the IC chip are electrically connected to the inner leads by bonding wires.

After wire bonding, the open cavity is filled with a filler gel, which completely seals the sensor chip and/or IC chips. The filler gel is, in one embodiment, typically a silicone gel such as those produced by Dow Corning and well known to those of skill in the art. In some embodiments, silicone oil may be used as a sealing material. For a pressure sensor package, the filler gel protects the pressure sensor die from the environment, yet is compressible and is capable of coupling pressure from the external environment to pressure sensor die.

The sensor package may be optionally capped by a lid after the open cavity is filled with the filler gel that encapsulates the sensor die and optional IC chips disposed on the bottom of the open cavity. The lid can be made by stamping or plating. The lid may be transparent so that the open cavity can be viewed even after the sensor package is capped by the lid. The lid may have a window through which the sensor package may function properly.

Singulation of the individual units from the full leadframe array strip is then performed either by saw singulation or die punching.

Referring now to FIGS. 5 and 6, there are illustratively shown two cross-sectional views of two sensor chips in accordance with the present invention. FIG. 5 shows sensor chip package having an open cavity formed by the bottom and sidewall 22. The bottom has the same thickness as the leadframe strip with external leads exposing to the outer surface and inner leads exposing to the open cavity. One or more die attach pads may be provided, but not shown herein. The chip 28 is attach to the bottom by the adhesive 27 and bonded to the inner leads by the bonding wires 29. The open cavity is filled with the filler gel 26 and capped with the lid 23. FIG. 6 shows a sensor chip package that is similar to the one shown in FIG. 5 but with some differences. The Inner leads are “stamped” or “bent” upward so that the thickness of the bottom of the open cavity is increased. In addition, the up-bended inner leads may optionally be supported by poles from the underneath (not shown).

While the present invention has been described with reference to particular embodiments, it will be understood that the embodiments are illustrative and that the invention scope is not so limited. Alternative embodiments of the present invention will become apparent to those having ordinary skill in the art to which the present invention pertains. Such alternate embodiments are considered to be encompassed within the spirit and scope of the present invention. Accordingly, the scope of the present invention is described by the appended claims and is supported by the foregoing description.

1. A sensor package, comprising:
a leadless frame having a plurality of inner leads and a plurality of external leads;
a molded structure forming an open cavity, wherein the leadless frame forms the bottom of the open cavity, and wherein the plurality of external leads expose to the outside of the open cavity and the plurality of inner leads expose to the inside of the open cavity;
a sensor die attached to the bottom of the open cavity;
a plurality of bond wires electrically connecting the sensor die with the plurality of inner leads; and
a filler gel filling the open cavity to encapsulate the sensor die and bond wires, wherein the filler gel has suitable characteristics for transducing a measurable parameter to the encapsulated sensor die.

2. The sensor package of claim 1, further comprising one or more IC chips attached to the bottom of the open cavity.

3. The sensor package of claim 1, further comprising a lid sealing the open cavity, wherein the lid has a window through which the encapsulated sensor can function properly.

4. The sensor package of claim 3, wherein the lid is transparent.

5. The sensor package of claim 1, wherein the sensor is selected from the group consisting of pressure sensor, accelerometer sensor, camera-image sensor, and IR/UV sensor.

6. The sensor package of claim 1, wherein the molded structure includes a plurality of cylindrical poles located at corners of the open cavity, thereby the corner poles strength the sensor package.

7. The sensor package of claim 1, wherein the leadless frame includes one or more inner connectors connecting two external leads respectively.

8. The sensor package of claim 7, wherein the inner connectors are half-etched from the bottom of the leadless frame so that the inner connectors are not exposed to the outside of the open cavity after the leadless frame is molded.

9. The sensor package of claim 1, wherein the leadless frame has no die attach pad.

10. The sensor package of claim 1, wherein the leadless frame has one or more die attach pads.

11. The sensor package of claim 1, wherein the thickness of the molded structure forming the bottom of the open cavity is variable for different sensors.

12. The sensor package of claim 11, wherein the thickness of the molded structure forming the bottom of the open cavity is increased by up-bending the inner leads prior to molding.

13. The sensor package of claim 12, wherein the up-bended inner leads may optionally be supported by poles from the underneath.

14. A method of manufacturing a sensor package, comprising steps of:
providing a leadless leadframe with a plurality of inner leads and a plurality of external leads;
molding the leadless leadframe to form a molded structure with an open cavity, wherein the leadless leadframe forms the bottom of the open cavity;
attaching a sensor die onto the bottom of the open cavity;
electrically connecting the sensor die and the plurality of inner leads by wire bonding; and
filling the open cavity with a filler gel, thereby the sensor die and bond wires are encapsulated by the filler gel.

15. The method of claim 14, further comprising the following step of:
attaching and electrically connecting one or more IC chips onto the bottom of the open cavity prior to the filling of the open cavity with the filler gel.

16. The method of claim 14, further comprising the following step of:
capping the open cavity with a lid after the filling of the open cavity by the filler gel, wherein the lid has a window through which the sensor can function properly.

17. The method of claim 16, wherein the lid is transparent.

18. The method of claim 14, further comprising the following step of:
singulating the sensor packages into individual ones.

19. The method of claim 18, wherein the singulation may be done by any method selected from the group consisting of sawing, punching, and laser cutting.
